(19) United States
(12) Patent Application Publication
(10) Pub. No.: US 2013/0284241 A1
(43) Pub. Date: Oct. 31, 2013

(54) Photovoltaic Module

(71) Applicant: SOLARWORLD INNOVATIONS GMBH, Freiberg (DE)

(72) Inventors: Matthias Georgi, Dresden (DE); Karl-Heinz Stegemann, Dresden (DE)

(73) Assignee: SolarWorld Innovations GmbH, Freiberg (DE)

(21) Appl. No.: 13/873,901

(22) Filed: Apr. 30, 2013

(30) Foreign Application Priority Data
Apr. 30, 2012 (DE) 202012004369.2

(51) Int. Cl. H01L 31/05; H01L 31/048

(52) U.S. Cl. CPC H01L 31/0504; H01L 31/048
USPC 136/251

(57) ABSTRACT

The present invention relates to a photovoltaic module comprising a front-side glass cover, a back-side cover and a number of interconnected solar cells. The solar cells are arranged in an embedding layer between the front-side and the back-side cover.

### CROSS-REFERENCE TO RELATED APPLICATIONS

This application claims the benefit of the filing date under 35 U.S.C. §119(a)-(d) of German Patent Application No. 20 2012 004 369.2, filed Apr. 30, 2012.

### FIELD OF THE INVENTION

The present invention relates to a photovoltaic module comprising a front-side cover, a back-side cover and a number of interconnected solar cells. The solar cells are arranged in an embedding layer between the front-side cover and the back-side cover.

### BACKGROUND

Solar cells are utilized in order to convert electromagnetic radiation energy, typically sunlight, into electric energy. The energy conversion is based on the fact that in a solar cell, radiation is subject to an absorption, thus generating positive and negative charge carriers (“electron hole pairs”). The free charge carriers thus generated are furthermore separated from each other in order to be discharged via separate contacts.

Established solar cells comprise a substrate made of silicon, the substrate having a square or substantially square outline. Two areas having different conductivities or, respectively, dopings are configured within the substrate. A p-n junction is present between the two substrate areas which are also referred to as “base” and “emitter”. This is attended by the existence of an inner electric field which causes the above-described separation of the charge carriers generated by means of radiation.

In a photovoltaic module, several solar cells operating according to this principle are connected to one another. In this context, the solar cells are arranged between a front-side and a back-side cover and in a transparent embedding layer. At the front side which during operation of the photovoltaic module faces the light radiation, a glass cover is generally used. The back-side cover may be realized as a plastic film.

### SUMMARY

Various aspects of the present invention provide an improved photovoltaic module.

One embodiment of the present invention provides photovoltaic module comprising a front-side glass cover, a back-side cover, and a number of interconnected solar cells. The solar cells are arranged in an embedding layer between the front-side and the back-side cover. The solar cells comprise a rectangular shape with an aspect ratio of 2:1.

Another embodiment of the present invention provides a photovoltaic module comprising a front-side glass cover, a back-side cover, and a number of interconnected solar cells. The solar cells are arranged in an embedding layer between the front-side and the back-side cover. The solar cells comprise a front-side contact structure, the front-side contact structure comprising a plurality of contact fingers and busbars running perpendicularly to the contact fingers. The contact fingers comprise a width in the area of 60 μm at most and a height-to-width aspect ratio of at least 1:2.

Another embodiment of the present invention provides a photovoltaic module comprising a front-side glass cover, a back-side cover, and a number of interconnected solar cells. The solar cells are arranged in an embedding layer between the front-side and the back-side cover. The solar cells comprise a dielectric layer and a back-side contact structure on a backside. The dielectric layer comprises strip-shaped openings. The back-side contact structure is arranged on the dielectric layer and in the strip-shaped openings of the dielectric layer.

### BRIEF DESCRIPTION OF THE DRAWINGS

These and other features of the present invention will become clear from the following description taken in conjunction with the accompanying drawings. It is to be noted, however, that the accompanying drawings illustrate only typical embodiments of the present invention and are, therefore not to be considered limiting of the scope of the invention. The present invention may admit other equally effective embodiments.

FIG. 1 shows a schematic lateral view of a photovoltaic module;

FIG. 2 shows a schematic top view of the photovoltaic module;

FIG. 3 shows a schematic lateral view of a solar cell substrate of a solar cell during production;

FIG. 4 shows a schematic view of a front side of the solar cell substrate during production;

FIG. 5 shows a schematic lateral view of the solar cell;

FIG. 6 shows a schematic view of the front side of the solar cell;

FIG. 7 shows a schematic view of a backside of the solar cell substrate during production;

FIG. 8 shows a schematic view of the backside of the solar cell; and

FIGS. 9 and 10 show schematic views of different interconnections of solar cells.

### DETAILED DESCRIPTION OF THE EMBODIMENT(S)

In the following, reference is made to embodiments of the invention. However, it should be understood that the invention is not limited to specific described embodiments. Instead, any combination of the following features and elements, whether related to different embodiments or not, is contemplated to implement and practice the invention. Furthermore, in various embodiments the invention provides numerous advantages over the prior art. However, although embodiments of the invention may achieve advantages over other possible solutions and/or over the prior art, whether or not a particular advantage is achieved by a given embodiment is not limiting of the invention. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

The present invention provides an embodiment of a photovoltaic module which comprises a front-side glass cover, a back-side cover and a number of interconnected solar cells. The solar cells comprise a rectangular shape with an aspect ratio of 2:1 and are arranged in an embedding layer between the front-side and back-side cover.

Such a configuration of the photovoltaic module comprising two covers and the solar cells arranged in between allows for suppressing or at least limiting a mechanical stress on the solar cells in case of a bending deformation of the photovoltaic module. This comes along with a high reliability of the photovoltaic module. The use of rectangular solar cells having an aspect ratio of 2:1 instead of conventional square solar cells allows for using twice the number of solar cells for the same module area in the photovoltaic module. Thereby, the solar cells may be interconnected in such a way that a high efficiency of the photovoltaic module may be achieved.

The two covers of the photovoltaic module which may both consist of glass may have the same thickness. As a result, the photovoltaic module may comprise a symmetric cross-sectional shape. Hereby, the solar cells may be located within a neutral bending zone which to a high extent allows for preventing a mechanical stress of the solar cells during a bending deformation of the photovoltaic module.

The solar cells with the aspect ratio of 2:1 used in the photovoltaic module may be produced from square solar cells which are each cut to obtain two solar cells. For such a “halving process”, it may be provided to scribe the solar cells on the backside by means of a laser beam and to subsequently break them mechanically.

With regard to an interconnection of the solar cells, a possible embodiment provides that the solar cells are connected to form several strings of solar cells connected in series by means of cell connectors. In each string, the rectangular solar cells are arranged with their long sides facing each other. Furthermore, two strings are respectively connected in parallel. The rectangular shape of the solar cells with the 2:1 aspect ratio instead of the conventional square shape allows for a configuration of a string which comprises twice as many solar cells than a comparable string of square cells. During operation, such a solar cell string may provide twice as much electric voltage. Contrary to a string configured of square solar cells, only half of the electric current flows. With the electric resistance of the cell connectors being the same, the result is a disproportionately lower power dissipation whereby a higher efficiency of the photovoltaic module may be achieved. Due to the parallel connection of two respective strings, the photovoltaic module may provide the same voltage as a conventional module configured of square solar cells.

With respect to an interconnection of the solar cells, it may furthermore be provided that solar cells of two solar cell strings connected in parallel, the solar cells being respectively arranged next to one another, are (additionally) connected in parallel. The parallel connection of individual solar cells allows for compensating currents flowing between the solar cells, thus e.g. reducing power losses due to partial shading. Furthermore, the solar cells connected in parallel may stem from the same, originally square solar cell which is cut accordingly. Due to the parallel connection, potential losses which may be caused by differing cell characteristics of the solar cells (cut in halves) may be limited or prevented.

In a further embodiment, the solar cells comprise silicon substrates having a substantially monocrystalline structure. Such monocrystalline silicon solar cells comprise a higher efficiency vis-à-vis polycrystalline silicon solar cells. Furthermore, substrates or, respectively, wafers having a predominantly monocrystalline silicon structure may be yielded from a silicon rod or, respectively, a silicon block which may be produced by means of an inexpensive casting process. In comparison thereto, a Czochralski pulling process usually carried out in connection with monocrystalline solar cells involves more costs and effort. Moreover, Czochralski wafers are usually produced with a pseudo-square shape with bevelled corners. As a result, a part of the module area of a module configured of such solar cells may not be used for solar energy generation. Solar cell substrates which are generated from a silicon block produced by casting may in contrast be provided without bevelled corners, thus preventing said disadvantage and achieving a performance gain.

Furthermore, the substrate of each solar cell of the photovoltaic module may comprise a pyramid-shaped surface texture on a front side. This allows for a reduced reflection and thus for an improved injection of the radiation into the solar cells during operation of the photovoltaic module in which the photovoltaic module and thus the solar cells face a light radiation with the front side. This promotes the efficiency of the photovoltaic module, as well. If, as described above, the solar cells comprise a silicon substrate with a substantially monocrystalline structure, the texture may be generated by means of an alkaline etching process.

Furthermore, the substrate of each solar cell of the photovoltaic module may comprise a whole-area antireflection layer on the front side. In this manner, as well, a reflection of light radiation at the front side of the solar cells and, as a result, an associated yield loss may be reduced or, respectively, suppressed.

In a further embodiment, the solar cells comprise silicon substrates having a surface being formed by sawing by means of a diamond wire.

In a further embodiment, the solar cells comprise a front-side contact structure by means of which the solar cells (or, respectively, their substrates) may be contacted at the front side. The front-side contact structure comprises a plurality of strip-shaped or, respectively, line-shaped contact fingers and busbars running perpendicularly to the contact fingers. Cell connectors provided for connecting the solar cells may be connected up to the busbars. The contact fingers may be arranged in parallel to the long side of the rectangular solar cells. Furthermore, the contact fingers may comprise a width of 60 μm at most and a height-to-width aspect ratio of at least 1:2. In this manner, the contact fingers only cause a relatively low shading of the front side of the solar cells. As a result, the solar cells and thus the photovoltaic module may exhibit high efficiency. Such contact fingers having a relatively small width and a relatively high aspect ratio may e.g. be produced by means of a coextrusion printing process. In this process, a metallic paste provided for the contact fingers is extruded on a solar cell substrate together with a supporting paste abutting on both sides of the metallic paste.

In a further embodiment, the solar cells comprise a front-side emitter which comprises a lowly doped large-area emitter region and a plurality of strip-shaped highly doped emitter regions. In this context, it is provided that contact fingers of a front-side contact structure of the solar cells are arranged on the strip-shaped highly-doped emitter regions. Such a selective emitter structure in which the strip-shaped emitter regions are more low-resistive than the plane emitter region arranged in between or, respectively, around, allows for reducing an undesired recombination of the charge carriers generated in the solar cells by radiation absorption. Furthermore, the absorption of short-wave radiation components may be increased. The low-resistive strip-shaped emitter regions may moreover provide a relatively small contact resistance to the contact fingers of the front-side contact structure. Hereby, a high efficiency of the solar cells and thus of the photovoltaic module is further promoted. The manufacturing of such an emitter structure may comprise carrying out a diffusion process for inserting a dopant into a solar cell substrate, followed by a selective or, respectively, local heating by means of a laser beam.

With regard to the above-described configuration comprising the antireflection layer, it may be provided that the contact fingers of the front-side contact structure extend through the antireflection layer to an associated solar cell substrate, i.e. to an emitter configured within the substrate (or, respectively, to strip-shaped highly doped emitter regions).

In a further embodiment, the solar cells comprise a dielectric layer and a back-side contact structure on a backside. The dielectric layer comprises strip-shaped openings which may run in parallel to the long side of the rectangular solar cells. In this context, the back-side contact structure is arranged on the dielectric layer and in the strip-shaped openings of the dielectric layer. The solar cells may be contacted at the backside by means of the back-side contact structure. The back-side contact structure of a solar cell may reach an associated substrate (or, respectively, a base formed in the substrate) by means of the openings in the dielectric layer. The back-side contact reduced in this embodiment to the area of the strip-shaped openings likewise provides the possibility of reducing a recombination of the charge carriers generated by means of radiation absorption. The dielectric layer further makes it possible that a radiation component penetrating a solar cell is reflected here and, as a result, may trigger the generation of additional charge carriers. This further promotes the achievement of a high efficiency of the solar cells and thus of the photovoltaic module.

The back-side contact structure may comprise a metallic layer and several busbars. Cell connectors which may be used in order to connect solar cells may be connected up to the busbars.

The metallic layer of the back-side contact structure may be formed from an inexpensive material, such as aluminium. The busbars may e.g. be made of silver. Furthermore, the solar cells may comprise an n-doped emitter which according to the above-described embodiment may comprise a lowly doped large-area emitter region and a plurality of strip-shaped highly doped emitter regions.

In a further embodiment, the photovoltaic module furthermore comprises a frame surrounding the front-side and the back-side cover. Thereby, the photovoltaic module may have a high mechanical stability.

Furthermore, other embodiments of a photovoltaic module may be considered, as well. One example is a photovoltaic module comprising a front-side cover, a back-side cover and a number of interconnected solar cells which are arranged in an embedding layer between the front-side and the back-side cover. Both covers may in this context be glass covers. An embodiment in which a glass cover is only provided at the front side and a different cover is provided at the backside, e.g. a back-side film or, respectively, a plastic film, is conceivable, as well. Furthermore, the solar cells may have a rectangular shape with an aspect ratio of 2:1 or a different shape such as a square or pseudo-square shape. For such embodiments of a photovoltaic module, the above-described configurations (e.g. the configuration of the solar cells with a substantially monocrystalline silicon substrate, with a front-side contact structure comprising contact fingers having a high aspect ratio, with a selective emitter and/or with a dielectric layer having strip-shaped openings at a backside etc.) may correspondingly be realized.

Further embodiments are explained in more detail in conjunction with the accompanying drawings.

The following figures serve to describe a photovoltaic module 200 which is characterized by high efficiency or, respectively, high performance. Individual features and components of the photovoltaic module 200 will be explained additionally in conjunction with a production process.

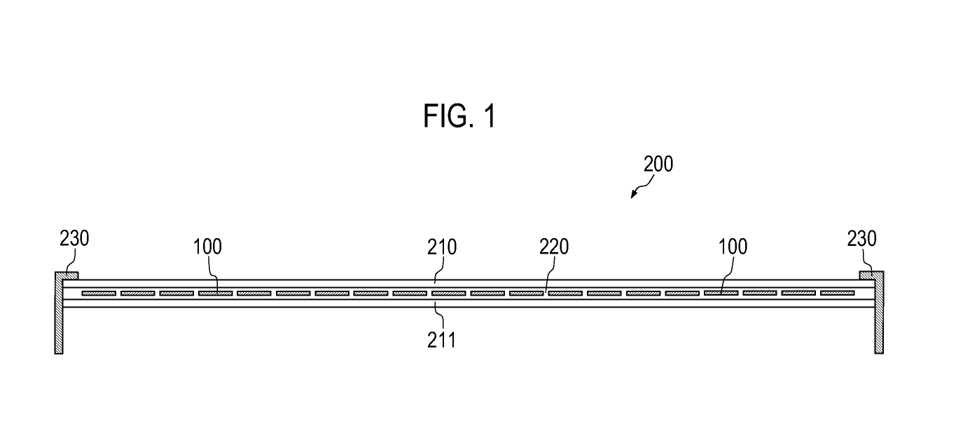

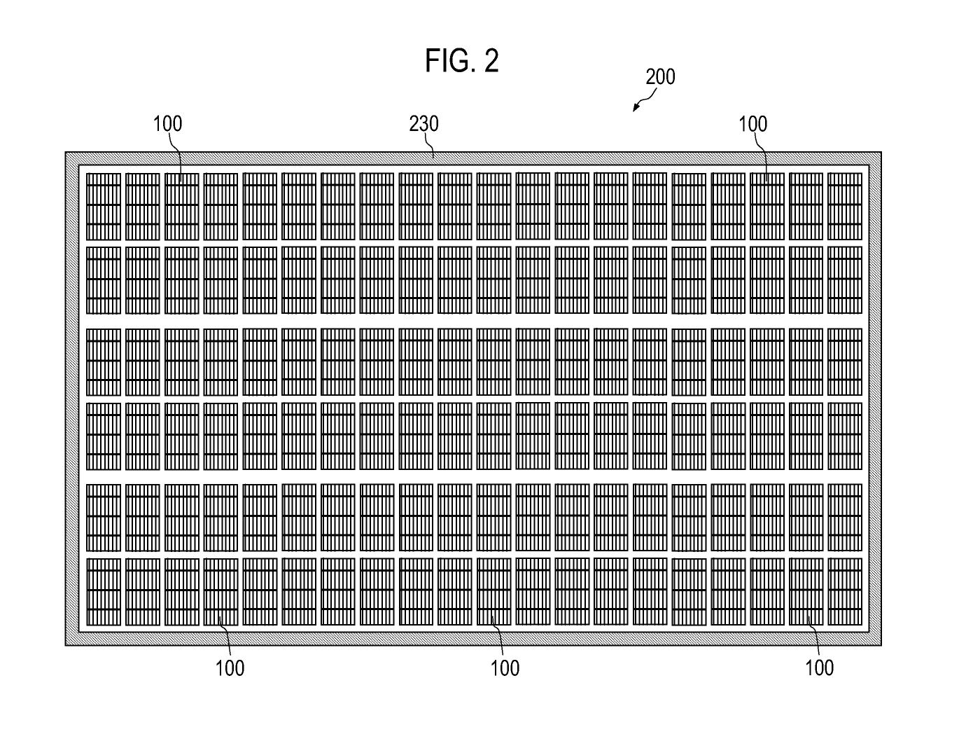

FIG. 1 shows a schematic lateral view of the photovoltaic module 200. An associated schematic top view which illustrates a front side of the photovoltaic module 200 is shown in FIG. 2. The photovoltaic module 200 which may also be referred to as solar module 200 comprises a number of electrically interconnected silicon solar cells 100. During operation, the photovoltaic module 200 faces a light radiation (sunlight) with its front side, whereby a part of the radiation may be absorbed by the solar cells 100 and be converted into electric energy.

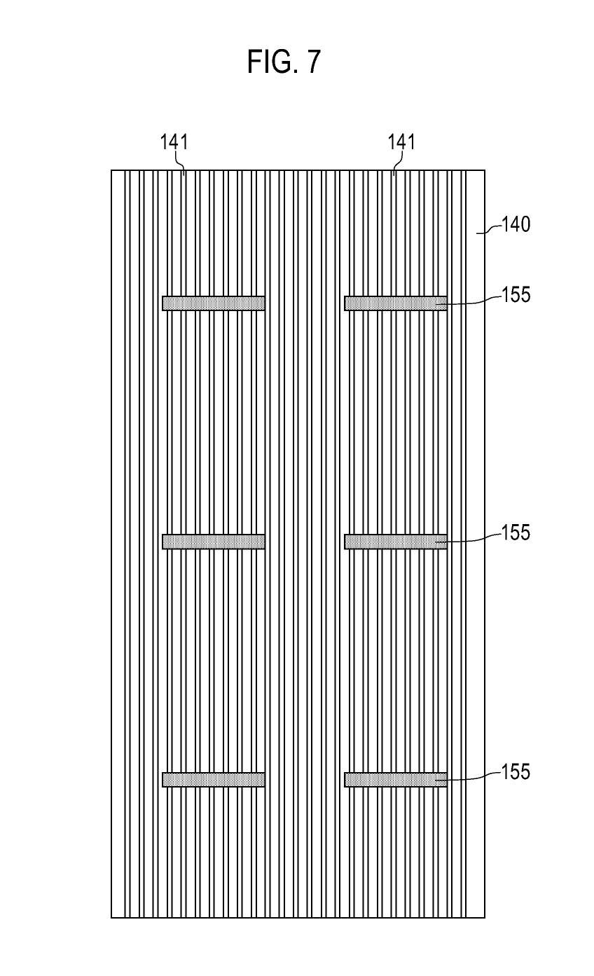

The solar cells 100 or, respectively, their substrates 110 have a rectangular outline with an aspect ratio of 2:1 (cf. FIGS. 2 and 6). Such a configuration of the solar cells 100 may be achieved by cutting square solar cells. As will be explained in more detail below, the rectangular shape instead of a square shape may be used for an interconnection of the solar cells 100 which promotes the efficiency of the photovoltaic module 200.

As shown in FIG. 1, the photovoltaic module 200 further comprises a front-side glass cover 210 and a back-side cover 211, wherein the latter may be made of glass, as well. The solar cells which are arranged in one plane are located between the two glass covers 210, 211 and are embedded in a transparent embedding layer 220 provided there. The embedding layer 220 may e.g. be made of ethylene vinyl acetate (EVA) or silicone. At the edge, the photovoltaic module 200 comprises a frame 230 which encloses the front-side and the back-side glass cover 210, 211 (and the embedding layer 220). The frame 230 which may confer a corresponding stability and torsional stiffness to the photovoltaic module 200 may comprise a plurality of (non-depicted) frame parts or, respectively, frame pieces, e.g. made of aluminium, and have e.g. an L-shaped profile, as shown in FIG. 1.

The configuration of the photovoltaic module 200 comprising the two glass panes 210, 211 and the solar cells 100 arranged in between allows for the possibility of reducing or suppressing a mechanical strain injection into the solar cells 100 in case of a bending deformation of the photovoltaic module 200. In order to promote this effect, the glass covers 210, 211 may have the same thickness. This is attended by a symmetrical cross-sectional shape of the photovoltaic module 200, thus providing a neutral bending zone in which the solar cells 100 may be located. In this manner, the photovoltaic module 200 may distinguish itself by high reliability. The two glass covers 210, 211 furthermore comprise a thickness of less than 2.5mm, thus enabling a low-weight photovoltaic module 200. In addition, a transmission of light radiation to the solar cells 100 through the front-side glass cover 210 may be enhanced.

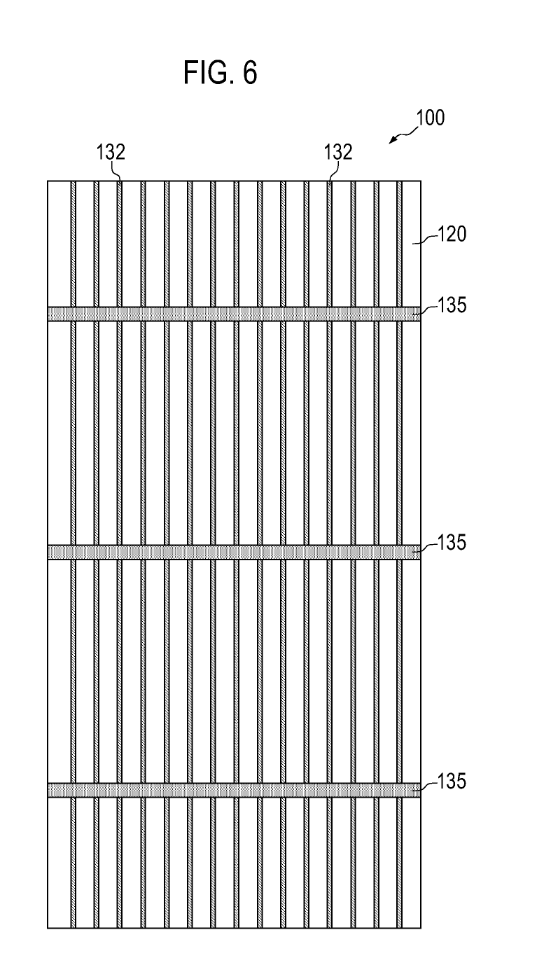

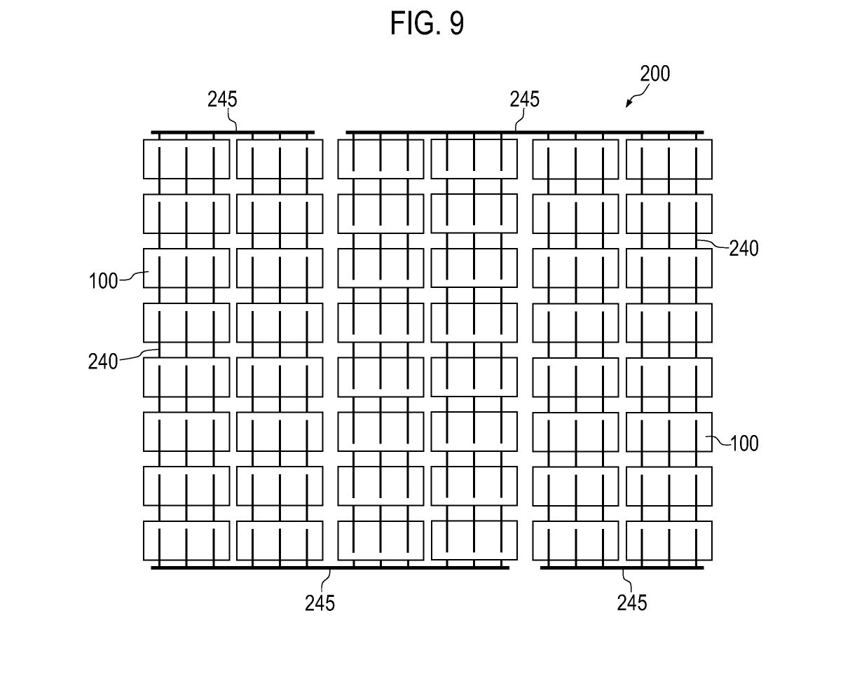

FIG. 5 shows a schematic lateral view or, respectively, a sectional view of a solar cell 100 of the photovoltaic module 200. A corresponding depiction of a front side of the solar cell 100 is shown in FIG. 6 and a view of a backside opposite to the front side is depicted in FIG. 8. The illustrated configuration described in the following and the advantageous effects connected thereto apply to all solar cells 100 used in the photovoltaic module 200.

As depicted in FIG. 5, the solar cell 100 comprises a substrate 110 of silicon which is divided up into substrate regions 111, 112 having different conductivities or, respectively, dopings. The substrate region present at the front-side area of the silicon substrate 110 is referred to as the emitter 112 and the other region is referred to as the base 111. In this context, the base 111 may comprise a p-doping and the emitter 112 may comprise an n-doping (p-type base, n-type emitter). A p-n junction is present between the base 111 and the emitter 112, the p-n junction generating an inner electric field within the substrate 110. Upon irradiating the solar cell 100 with light radiation, a separation of the charge carriers generated in the substrate 110 by radiation absorption may be effected in this manner. Thereby, the solar cell 100 faces the light with its front side.

In order to be able to contact the poles of the p-n junction, i.e. the base 111 and the emitter 112, corresponding contact structures are arranged at the front side and backside of the substrate 110. The front-side contact structure comprises a plurality of metallic contact elements 132 which reach the substrate 110 or, respectively, the emitter 112. The contact elements 132 which in the following will be referred to as contact fingers 132 are relatively thin and strip- or, respectively, line-shaped, as shown in FIG. 6, and run in parallel to the long side of the rectangular solar cell 100. The thin shape allows for a low shading of the front side of the solar cell 100.

FIG. 5 makes it clear that the solar cell 100 furthermore comprises an antireflection layer 120 arranged on the substrate 110 at the front side. The antireflection layer 120 may e.g. be made of silicon nitride. The strip-shaped contact fingers 132 of the front-side contact structure extend through the antireflection layer 120 to the substrate 110. By means of the antireflection layer 120, a reflection of light radiation at the front side of the solar cell 100 and yield losses connected thereto may be reduced or, respectively, suppressed.

For the same purpose, the substrate 110 of the solar cell 100 is formed with a front-side surface texture (not shown). The texture which may be in the form of a pyramid-shaped surface structure may also allow for a reduced reflection and thus for an improved injection of the radiation into the solar cell 100 at its front side.

In addition to the contact finger structure with the contact fingers 132, the front-side metallization of the solar cell 100 comprises, as shown in FIG. 6, several metallic contact elements 135 (three in the present example) which in the following will be referred to as busbars 135. The strip-shaped busbars 135 are arranged on the antireflection layer 120 and on the contact fingers 132. The busbars 135 which have a larger width than the contact fingers 132 run perpendicularly to the contact fingers 132 or, respectively, in parallel to the short side of the solar cell 100. The busbars 135 are used to connect up cell connectors by means of which two solar cells 100 may be electrically connected to each other. The contact fingers 132 as well as the busbars 135 may e.g. comprise silver.

FIG. 5 further illustrates that the front-side emitter 112 of the solar cell 100 is configured as a selective emitter structure and comprises a large-area or, respectively, whole-area emitter region 114 and a plurality of strip- or, respectively, line-shaped emitter regions 115. The emitter regions 115 reaching the front-side substrate surface, like the strip-shaped contact fingers 132 of the front-side contact structure, run in parallel to the long side of the rectangular solar cell 100. In this context, the contact fingers 132 and the emitter regions 115 are adjusted to each other or, respectively, the contact fingers 132 adjoin the emitter regions 115. The strip-shaped emitter regions 115 have a (substantially) higher doping density than the emitter region 114 which is located in between or around, and they are thus more low-resistive than the lowly doped emitter region 114.

Such a selective emitter 112 comprising regions 114, 115 with different doping concentrations offers a plurality of advantages. Compared to the strip-shaped emitter regions 115, the emitter region 114 has a lower doping density, by means of which an undesired recombination of the charge carriers generated by radiation absorption in the solar cell 100 may be reduced. Further, the absorption of short-wave radiation components may be increased. Due to the highly doped and thus low-resistive emitter regions 115, a relatively small electric transition resistance is furthermore present with regard to the contact fingers 132 of the front-side contact structure.

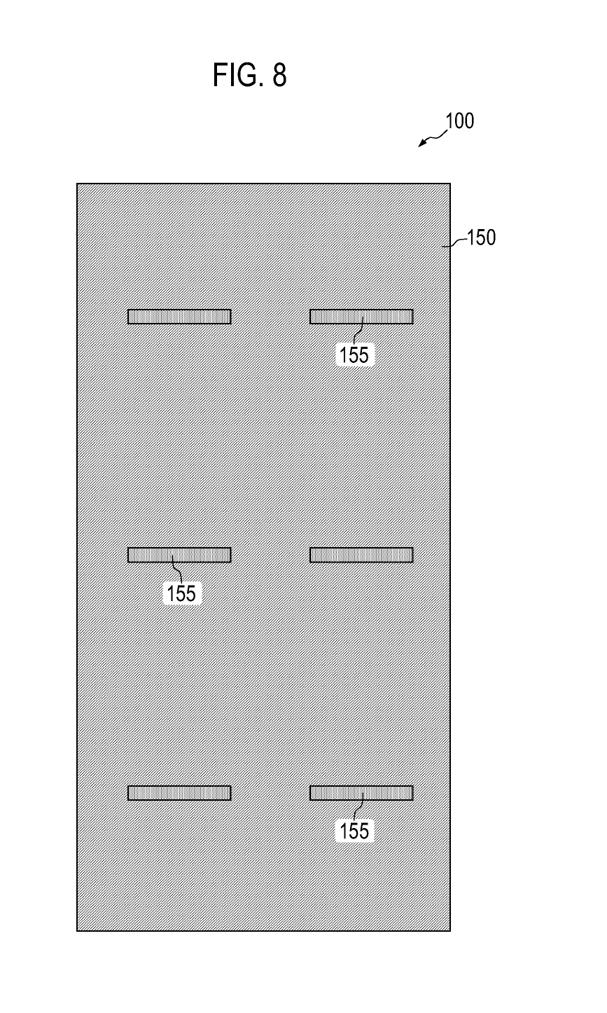

At the backside, the solar cell 100 comprises an arrangement of a dielectric layer 140 and a back-side contact structure 150, 155, as is obvious from FIGS. 5 and 8. The dielectric layer 140 arranged on the substrate 110 of the solar cells 100, which may e.g. be configured in the form of a stack of silicon oxynitride and silicon nitride, comprises a plurality of openings 141. The openings 141 are strip- or, respectively, line-shaped and may run in parallel to the long side of the rectangular solar cell 100 (cf. FIG. 7).

As depicted in FIG. 8, the back-side contact structure comprises a metallic layer 150 and several metallic contact elements 155 (six in the present example) which will be referred to as busbars 155 in the following. The metallic layer 150 may e.g. comprise aluminium and the busbars 155 may e.g. comprise silver. The metallic layer 150 which in the region of the strip-shaped busbars 155 is omitted or, respectively, opened may slightly overlap the busbars 155 at the edge. The busbars 155 which are (also) used to connect up cell connectors run in parallel to the short side of the rectangular solar cell. Contrary to the front-side busbars 135, the back-side busbars 155 are configured with a shorter length. As shown in FIG. 8, two busbars 155 are herein in each case arranged next to one another or, respectively, on a common straight line.

The metallic layer 150 and the busbars 155 are arranged on the dielectric layer 140 as well as in the openings 141 of the dielectric layer 140. Thereby, the layer 150 and the busbars 155 may directly reach the substrate 110 (or the base 111) in the area of the openings 141 and thus contact the substrate 110. The back-side contact reduced in this manner to the area of the strip-shaped openings 141 of the dielectric layer 140 (also) provides the possibility of reducing a recombination of the charge carriers generated by radiation absorption within the solar cell 100. The dielectric layer 140 further allows for a reflection of a radiation component penetrating the substrate 110 of the solar cell 100, by means of which additional charge carriers may be generated in the solar cell 100.

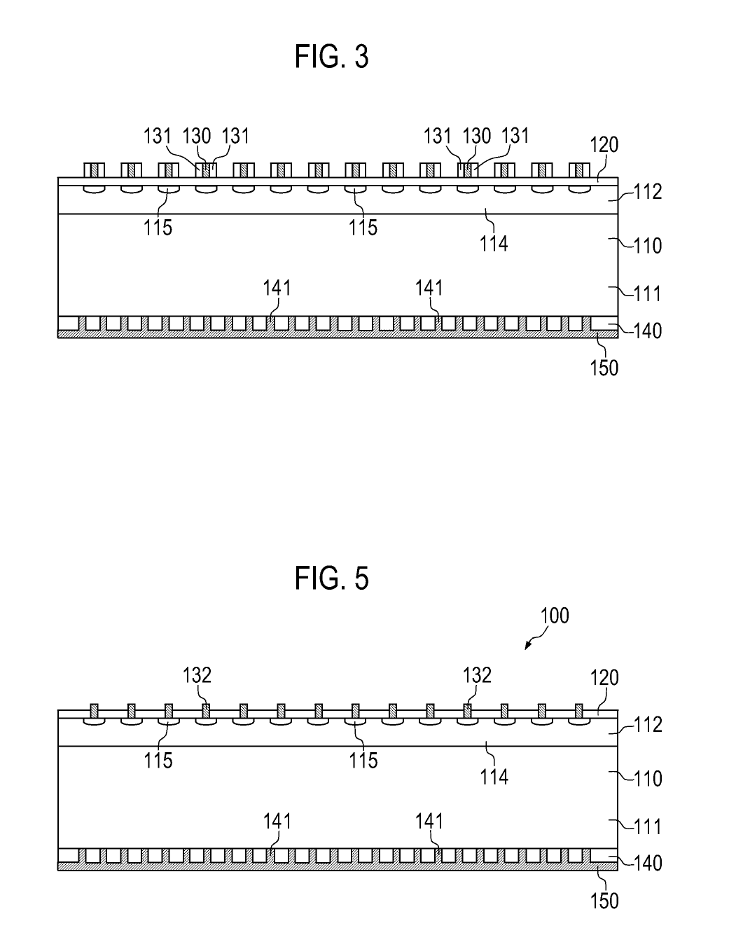

Further details with regard to the solar cell(s) 100 and the photovoltaic module 200 will be described in more depth in the following in conjunction with a potential production method. Thereby, reference is partly made to FIGS. 3, 4 and 7 in which a substrate 110 of a not yet finished solar cell 100 is shown in the stages of its production. Although the substrate 110 has in this case a square outline and not (yet) a rectangular shape with a 2:1 aspect ratio, FIGS. 3, 4 and 7 are depicted in conformity with FIGS. 5, 6 and 8 for clarity's sake. In this regard, FIGS. 3, 4 and 7 may be seen as sectional views of the respective substrate 110.

It is provided for the solar cells 100 to use silicon substrates 110 with a substantially monocrystalline crystal structure. Such substrates or, respectively, wafers 110 are produced by cutting (sawing) a silicon rod or block, the production of which may be carried out by means of an inexpensive casting process (not shown).

In general, polycrystalline silicon blocks are produced by means of a casting method, from which polycrystalline wafers and solar cells may correspondingly be manufactured. This may be achieved by a directed solidification of molten silicon in an ashlar-shaped crucible without the provision of a seed. However, polycrystalline solar cells only have a relatively low efficiency.

In comparison, monocrystalline cells have a higher efficiency. The manufacturing of monocrystalline silicon rods has been carried out for decades by means of the so-called Czochralski pulling process. In this process, a rotating seed is dipped into a liquid silicon melt and slowly withdrawn according to the crystal growth so that a circular cylindrically shaped silicon rod is produced. However, the pulling process is relatively complex and expensive. Furthermore, substrates having a pseudo-square shape with bevelled corners are usually manufactured from such a rod. When using solar cells gained therefrom in a module, a part of the module area cannot be used for solar energy recovery.

In order to avoid such disadvantages, it is provided within the framework of the solar cell manufacture for the photovoltaic module 200 to carry out a casting process in order to produce a substantially monocrystalline silicon block. In this context, the casting process comprises the directed solidification of molten silicon in an ashlar-shaped crucible by using one or several monocrystalline seeds at the bottom of the crucible, wherein the seed(s) is/are not completely molten when melting the silicon. In this manner, the solidifying silicon may take over the crystal orientation of the seed or, respectively, the seeds, which confers a predominantly monocrystalline structure to the silicon block. This is a 100-crystal orientation. For the further production, it is provided to cut or, respectively, to saw the block into rods having a square cross-section and the rods into substrates 110.

Such a “quasi-mono process” is less expensive than the usually used Czochralski pulling process, however, it also allows for the manufacture of monocrystalline substrates 110 and thus solar cells 100 having a high efficiency. Furthermore, (differing from Czochralski wafers) the associated solar cell substrates 110 do not have bevelled corners, which allows for a better utilization of the module area of the photovoltaic module 200.

The substrates 110 are furthermore provided with a p-conducting basic doping. For this purpose, it is provided within the framework of the casting process to add the dopant boron to the silicon raw material prior to or during melting, which provides a positive or, respectively, p-conducting basic doping of the solidified silicon block and thus of the substrates 110 produced therefrom.

A substrate 110 produced in this manner is furthermore subjected to an etching process in order to form a (front-side) surface texture. Within the framework of the etching process, a sawing damage connected to the cutting of the cast silicon block may be removed, as well. With regard to the above-indicated 100-crystal orientation, the substrate surface comprises a 100-direction. In such a case, the etching process may be carried out with an alkaline etching solution, e.g. potassium hydroxide (KOH). Thereby, a pyramid structure is exposed on the substrate surface which may provide an effective injection of incident light radiation and thus a maximum radiation absorption in the solar cell 100.

After forming the texture, a selective n-conductive emitter 112 is formed. For this purpose, the substrate 110 provided with the p-conductive basic doping is subjected to a diffusion process, by means of which a (relatively thin) region in the area of the front-side surface is provided with an n-doping and as a result, a plane emitter region 114 is formed (cf. FIGS. 3 and 5). Thus, a base-emitter structure (p-type base 111, n-type emitter 112, 114) or, respectively, a p-n junction is present in the substrate 110. In order to produce the emitter region 114, it is provided to diffuse phosphorus into the texturized substrate surface which may e.g. be carried out by means of processing the substrate 110 in a furnace having a phosphorus-containing ambient.

After producing the whole-area emitter region 114, strip-shaped and highly doped emitter regions 115 are generated at those locations where in a later stage of the production method strip-shaped contact fingers 132 are formed on the front side of the substrate 110. This is carried out by means of a laser, the beam of which may be utilized for strip-shaped or, respectively, line-shaped heating of the substrate 110. In this manner, phosphorus introduced into the substrate 110 may additionally be activated locally, which forms the highly doped emitter regions 115 shown in FIGS. 3 and 5. The strip-shaped heated regions and thus the emitter regions 115 may have a width of approximately 300 μm and a distance of approximately 2mm. Alternatively or additionally, it is conceivable that a doping source being present in the area of the front side of the substrate 110, the doping source e.g. being a phosphorus silicate glass (PSG) generated during the above-described diffusion process, is selectively heated by means of a laser. As a result, additional phosphorus from the doping source may be driven into the substrate 110 at these locations. The PSG glass may be removed by means of a subsequent etching process.

The front-side (texturized) surface of the substrate 110 is further provided with an antireflection layer 120 upon forming the selective emitter 112 (cf. FIG. 3). This may be carried out by applying silicon nitride over the entire area of the substrate front side by means of a plasma-enhanced chemical vapour deposition (PECVD). The silicon nitride may in this process be deposited with a layer thickness of approximately 70 nm.

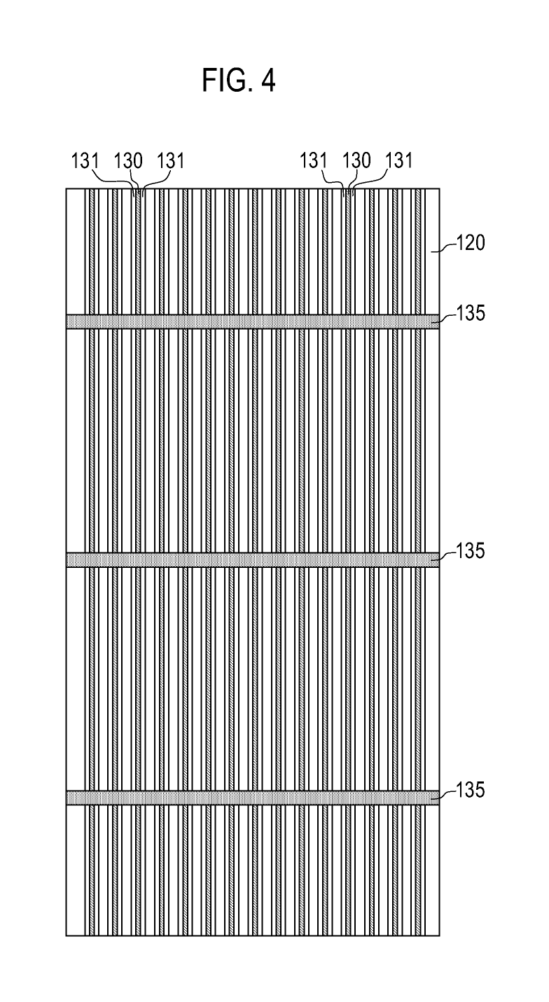

On the front side of the substrate 110 coated with the antireflection layer 120, a contact structure comprising strip-shaped contact fingers 132 and busbars 135 running transversely to the contact fingers 135 is furthermore formed. The contact fingers 132 are formed by means of a coextrusion printing process. In this process, strips of a metal paste 130 for the contact fingers 132 are extruded on the antireflection layer 120 together with a supporting paste 131 (cf. FIGS. 3 and 4). In this context, the supporting paste 131 abuts on both sides of the extruded metal paste 130. The strips of the metal paste 130 from which the contact fingers 132 provided for contacting the highly doped emitter regions 115 are being produced, are in this process arranged as precisely as possible on top of the emitter regions 115.

Due to the use of the supporting paste 131 resting against both sides of the metal paste 130, the contact fingers 132 may be formed with a small width and a high height-to-width aspect ratio (referring to the cross-section). In this context, the aspect ratio may be higher than in other printing or, respectively, depositing processes such as a screen printing or a simple extrusion printing process. The metal paste 130 used for the contact fingers 132 is a silver-containing paste comprising silver particles and etching additives. The supporting paste 131 comprises an organic material or, respectively, a polymeric material.

In the following, a further silver-containing paste (without etching additives) is deposited on the strips of the metallic paste 130, on the surrounding supporting paste 131 and on the antireflection layer 120 by means of a screen printing process in order to form the busbars 135 which run at right angles to the contact fingers 132 (cf. FIG. 4).

Moreover, a high-temperature process referred to as “firing” or “curing” is carried out by means of which the strips of the metal paste 130 and the busbars 135 (provided in paste-like form) may be solidified or, respectively, cured. The etching additives contained in the metal paste 130 may in this process further cause an etching through the antireflection layer 120. Due to this, the contact fingers 132 formed by solidification of the metal paste 130 may be connected to the substrate 110 through the antireflection layer 120 and thus contact the highly doped emitter regions 115 (cf. FIG. 5). At the same time, the organic supporting paste 131 evaporates during curing. The remaining contact fingers 132 may have a height in the area of about 20 μm to 30 μm and a width in the area of about 40 μm to 60 μm. Furthermore, the contact fingers 132 may have a relatively high height-to-width ratio in the area of 1:2 or, respectively, at least 1:2. This leads to a relatively low coverage of the front side of the solar cell 100.

The high-temperature step may simultaneously be used for finishing a back-side contact structure. Prior to forming such a contact structure, at first a structured dielectric layer 140 comprising openings 141 is formed on the backside of the substrate 110 (cf. FIGS. 3 and 7). The deposition of the dielectric layer 140 may be carried out by means of a PECVD process in which a stack of silicon oxynitride and silicon nitride is deposited on the entire area of the substrate backside in a two-stage process. The layer thickness may be in the area of about 150 nm to 200 nm. Subsequently, strip-shaped openings 141 are generated in the dielectric layer 140 by means of a laser beam. By means of the openings 141, the back-side surface of the substrate 110 is again exposed at these locations. The strip-shaped openings 141 which are formed running in the same direction as the emitter regions 115 and the contact fingers 132 may have a width of about 30 μm to 60 μm and a distance of about 1 mm.

In order to form the back-side contact structure, at first a silver-containing paste for busbars 155 is printed on the backside or, respectively, on the dielectric layer 140 and into the openings 141 by means of a screen printing process (cf. FIG. 7). In a second screen printing process, an aluminium-containing paste for a metallic layer 150 is printed on the backside or, respectively, on the dielectric layer 140 and into the openings 141 (cf. FIGS. 3 and 8). The paste for the metallic layer 150 covers the entire backside except for the (paste-like) busbars 155 printed previously and may slightly overlap these at the edge. By means of the two screen printing processes, the corresponding pastes may each be printed with a layer thickness in the area of about 10 μm to 20 μm. Due to the subsequent high-temperature step (“curing”), the paste-like metallic layer 150 and the busbars 155 may be cured and connected to the substrate 110 or, respectively, the base 111.

Upon completion of these process steps, a solar cell 100 ready for use in the photovoltaic module 200 is substantially finished. At this stage, however, the solar cell 100 still has a square outline. In a further step, the solar cell 100 is thus cut or, respectively, halved, thus producing two solar cells 100 having a rectangular shape with a 2:1 aspect ratio. It may be provided for the cutting process to scribe the respective square solar cell 100 on the backside by means of a laser beam and to subsequently break it mechanically. The scribing is carried out in such a way that the laser beam does not penetrate to the emitter 112 or, respectively to the lowly doped emitter region 114 from the backside so that a cell short which may be caused thereby is prevented. In this process, the square solar cell 100 is cut in such a way that the number of the contact fingers 132 and of the back-side busbars 155 as well as the length of the front-side busbars 135 is halved. In the halved solar cells 100, the contact fingers 132, the emitter regions 115 and the openings 141 of the dielectric layer 140 extend in parallel to the long side, whereas the busbars 135, 155 run transversely thereto and thus in parallel to the short side.

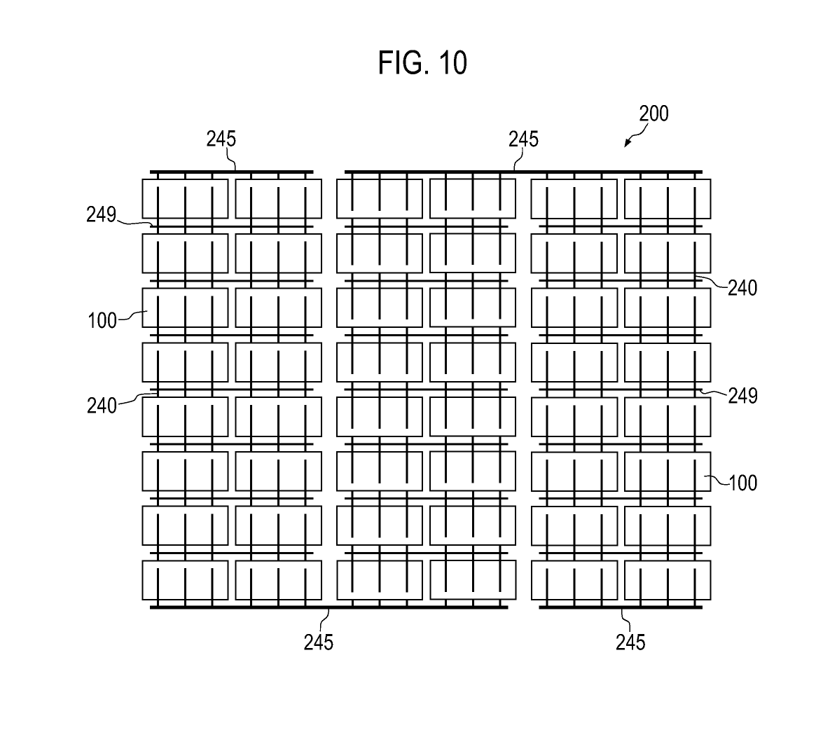

The photovoltaic module 200 shown in FIGS. 1 and 2 may subsequently be configured from a plurality of solar cells 100 produced and cut in this manner. For this purpose, the halved solar cells 100 are electrically interconnected according to a predefined circuit scheme. In this context, electrical connection elements, e.g. cell connectors, are used which are connected up to the front-side and back-side busbars 135, 155 of the solar cells 100 by means of soldering. Potential circuitries which may be used for the photovoltaic module 200 are explained in more detail in conjunction with FIGS. 9 and 10.

The interconnected solar cells 100 are further subjected to a lamination process in order to form the structure illustrated in FIG. 1, according to which the solar cells 100 are arranged in an embedding layer 220 between two glass covers 210, 211. This may be carried out by providing one of the two glass panes 210, 211 and by subsequently arranging a first partial layer of an embedding material (EVA or silicon), the interconnected solar cells 100, a further partial layer of the embedding material and the other of the two glass panes 211 thereon. For the actual lamination, this arrangement is heated and pressed or, respectively, subjected to an overpressure. As a result, the partial layers of the embedding material may melt and form the transparent embedding layer 220 in which the solar cells 100 are embedded from both sides. The solar cells 100 are connected with the two glass panes 210, 211 via the embedding layer 220.

The composite produced in this way is furthermore provided with a surrounding frame 230, as shown in FIGS. 1 and 2. For this purpose, a plurality of frame profiles which may be provided in the form of continuously cast profiles made of aluminium may be arranged at the composite. The frame profiles may have a cross-sectional L-shape, as indicated in FIG. 1, or alternatively a different shape, such as an F-shape. Furthermore, the frame profiles may also comprise a hollow chamber by means of which an increased rigidity may be achieved. At their ends, the frame profiles may be cut to a 45°-mitre or they may be cut to be edgeless. In the first variant, the frame profiles may be arranged in an abutting manner. In the second variant, 90°-corner connections may additionally be utilized at the four corners of the composite. These may be dead-mould casting pieces made of aluminium. In order to fix the frame parts, techniques such as gluing, screwing, pressing etc. may be used.

Regarding an interconnection of the solar cells 100, several strings of solar cells 100 connected in series are used in the photovoltaic module 200. In this respect, six such strings extending in parallel to the long side of the rectangular module 200 are indicated in FIG. 2. The solar cells 100 of a string are each arranged with their long sides in opposite orientation with regard to one another.

An associated circuit scheme which may be provided for the photovoltaic module 200 is schematically depicted in FIG. 9. The solar cells 100 are hereby arranged to form six strings, as well, which in the illustration of FIG. 9, however, run vertically, contrary to FIG. 2. In the individual strings, the solar cells 100 are serially connected with one another by means of cell connectors 240. The cell connectors 240 which may be in the form of copper bands are connected up to the front-side and back-side busbars 135, 155 of the solar cells 100 shown in FIGS. 6 and 8. A cell connector 240 thereby respectively connects the front-side and back-side busbars 135, 155 of two neighbouring solar cells 100 of the same string, as indicated in FIG. 9.

The shape of the solar cells 100 with the 2:1 aspect ratio instead of the usual square shape allows for a string being able to comprise twice as many solar cells 100 than a string of uncut square cells. When operating the photovoltaic module 200, twice the electric voltage may consequently be generated by means of the string. Contrary to a string of square cells, however, only half of the electric current flows. The result of this, provided that the electric resistance of the cell connectors 240 is the same, is a disproportionately lower power dissipation.

This results from P=I²*R, wherein P is the power (dissipation), I the current and R the resistance of the cell connectors 240. The photovoltaic module 200 configured of strings of halved solar cells 100 may thus provide a higher performance.

As is furthermore indicated in FIG. 9, two solar cell strings are each connected in parallel, wherein the parallelly-connected solar cell strings are connected in series with regard to one another. In this context, corresponding transverse connectors 245 are used at the edge of the solar cell strings which are in turn connected up to the front-side and back-side busbars 135, 155 of the solar cells 100 (via cell connectors 240). Due to the parallel connection of two respective strings, the photovoltaic module 200 may provide the same voltage as a conventional module comprising a series connection of uncut square cells.

FIG. 10 shows a further potential circuit scheme for the photovoltaic module 200 which is a further implementation of the circuit scheme of FIG. 9. Here, it is provided that in each case solar cells 100 of two parallelly-connected solar cell strings, the solar cells 100 being in each case arranged side-by-side, are additionally connected in parallel. This is realized by means of parallel connectors 249 which are connected to cell connectors 240 of the two solar cell strings and thus connect the same to one another. By means of the parallel connection of individual solar cells 100 realized in this manner it is possible that compensating currents may flow between the solar cells 100. Hereby, performance losses caused by a partial shading of solar cells 100 may be reduced.

With regard to the solar cells 100 respectively connected in parallel among one another and arranged side-by-side (horizontally side-by-side in FIG. 10), it is further provided that these solar cells 100 each originate from the same, originally square cell. In this manner, possible losses which may be a result of the different cell characteristics of the (halved) solar cells may be limited or prevented.

The embodiments explained in conjunction with the Figures are exemplary embodiments of the invention. Apart from the described and depicted embodiments, further embodiments are conceivable which may comprise further variations or, respectively, combinations of features.

It is e.g. possible that other materials are utilized instead of the above-indicated materials for the solar cells and the photovoltaic module. The same applies to dimensions (e.g. layer thicknesses, widths, distances etc.) which may be replaced by other specifications. Furthermore, a base and a (selective) emitter of a solar cell may be configured with opposite conductivities, i.e. an n-type base and a p-type emitter.

Apart from the above-described components, a photovoltaic module may comprise further components such as a connecting box. Moreover, instead of six solar cell strings in which the solar cells are connected in series and arranged opposite to one another with their long sides, a different number of solar cell strings may be provided. In this context, as well, two strings may respectively be connected in parallel in accordance with FIG. 9, and in addition, an arrangement according to FIG. 10 may be utilized. Moreover, other interconnections of solar cells are possible.

Modifications are also conceivable for the above-described method for producing the solar cells and the photovoltaic module. For example, further processes may be carried out or processes may be executed in a different order. It is furthermore possible to deposit a front-side contact structure (in a paste-like form) before or, alternatively, after depositing a back-side contact structure. Hardening or curing of the two contact structures may be carried out as described above in a joint temperature process, or alternatively in separate temperature processes.

The preceding description describes exemplary embodiments of the invention. The features disclosed therein and the claims and the drawings can, therefore, be useful for realizing the invention in its various embodiments, both individually and in any combination. While the foregoing is directed to embodiments of the invention, other and further embodiments of this invention may be devised without departing from the basic scope of the invention, the scope of the present invention being determined by the claims that follow.

What is claimed is:

1. A photovoltaic module comprising:
a front-side glass cover;
a back-side cover; and
a number of interconnected solar cells which are arranged in an embedding layer between the front-side cover and the back-side cover, the solar cells comprising a rectangular shape with an aspect ratio of 2:1.

2. The photovoltaic module according to claim 1, wherein the solar cells are connected to form several strings of solar cells connected in series by means of cell connectors, the solar cells being in each string arranged facing one another with their long sides, and two strings being respectively connected in parallel.

3. The photovoltaic module according to claim 2, wherein solar cells of two strings connected in parallel are respectively arranged next to one another and are additionally connected in parallel.

4. The photovoltaic module according to claim 1, wherein the back-side cover consists of glass.

5. The photovoltaic module according to claim 1, wherein the solar cells comprise silicon substrates having a substantially monocrystalline structure and, on a front side, a pyramid-shaped surface texture and an antireflection layer.

6. The photovoltaic module according to claim 1, wherein the solar cells comprise silicon substrates having a surface being formed by sawing with a diamond wire.

7. The photovoltaic module according claim 1, wherein the solar cells comprise a front-side contact structure, the front-side contact structure comprising a plurality of contact fingers and busbars running perpendicularly to the contact fingers, and the contact fingers being arranged in parallel to a long side of the solar cells and having a width of about 60 μm or less and a height-to-width aspect ratio of at least 1:2.

8. The photovoltaic module according to claim 1, wherein the solar cells comprise a front-side emitter, the emitter comprising a lowly doped large-area emitter region and a plurality of strip-shaped highly doped emitter regions, and contact fingers of a front-side contact structure of the solar cells being arranged on the strip-shaped highly-doped emitter regions.

9. The photovoltaic module according to claim 1, wherein the solar cells comprise a dielectric layer and a back-side contact structure on a backside, the dielectric layer comprising strip-shaped openings which run in parallel to the long side of the solar cells, and the back-side contact structure being arranged on the dielectric layer and in the strip-shaped openings of the dielectric layer.

10. The photovoltaic module according to claim 9, wherein the back-side contact structure comprises a metallic layer and several busbars.

11. The photovoltaic module according to claim 10, wherein the metallic layer comprises aluminium and wherein the solar cells comprise an n-doped front-side emitter.

12. The photovoltaic module according to claim 1, further comprising a frame surrounding the front-side and back-side cover.

13. A photovoltaic module comprising:
a front-side glass cover;
a back-side cover; and
a number of interconnected solar cells which are arranged in an embedding layer between the front-side and the back-side cover, wherein the solar cells comprise a front-side contact structure, the front-side contact structure comprising a plurality of contact fingers and busbars running perpendicularly to the contact fingers, and the contact fingers having a width of about 60 μm or less and a height-to-width aspect ratio of at least 1:2.

14. The photovoltaic module according to claim 13, wherein the solar cells comprise a front-side emitter, the emitter comprising a lowly doped large-area emitter region and a plurality of strip-shaped highly doped emitter regions, and contact fingers of the front-side contact structure of the solar cells being arranged on the strip-shaped highly-doped emitter regions.

15. The photovoltaic module according to claim 13, wherein the solar cells comprise silicon substrates having a substantially monocrystalline structure and, on a front side, a pyramid-shaped surface texture and an antireflection layer.

16. A photovoltaic module comprising:
a front-side glass cover;
a back-side cover; and
a number of interconnected solar cells which are arranged in an embedding layer between the front-side and the back-side cover, wherein the solar cells comprise a dielectric layer and a back-side contact structure on a backside, the dielectric layer comprising strip-shaped openings, and the back-side contact structure being arranged on the dielectric layer and in the strip-shaped openings of the dielectric layer.

17. The photovoltaic module according to claim 16, wherein the back-side contact structure comprises a metallic layer and several busbars.

18. The photovoltaic module according to claim 17, wherein the metallic layer comprises aluminium and wherein the solar cells comprise an n-doped front-side emitter.

19. The photovoltaic module according to claim 16, wherein the solar cells comprise silicon substrates having a substantially monocrystalline structure and, on a front side, a pyramid-shaped surface texture and an antireflection layer.
